(19) United States
(12) Patent Application Publication
(10) Pub. No.: US 2014/0014179 A1
(43) Pub. Date: Jan. 16, 2014

(54) MULTI-LAYER, LIGHT-MODULATING DEVICES AND THE MANUFACTURER THEREOF

(71) Applicants: Gerhard Frederick Swiegers, Wollongong (AU); David Leslie Officer, Wollongong (AU); Gordon George Wallace, Wollongong (AU)

(72) Inventors: Gerhard Frederick Swiegers, Wollongong (AU); David Leslie Officer, Wollongong (AU); Gordon George Wallace, Wollongong (AU)

(73) Assignee: UNIVERSITY OF WOLLONGONG, Wollongong, NSW (AU)

(21) Appl. No.: 13/992,890

(22) PCT Filed: Dec. 9, 2011
(86) PCT No.: PCT/AU2011/001602

§ 371 Date: Sep. 27, 2013

(30) Foreign Application Priority Data
Dec. 10, 2010 (AU) 2010905436

(51) Int. Cl. H01L 31/0203; G02F 1/161

(52) U.S. Cl. CPC H01L 31/0203; G02F 1/161
USPC 136/259; 438/64; 359/265; 156/60

(57) ABSTRACT

A light-modulating electrical device is disclosed and a method for manufacturing a light-modulating electrical device. The method includes, as a single lamination process, positioning a light-modulating electrical unit at least partially within a recess, the recess provided in a first polymer film or an optically transparent polymer film, and fixing the optically transparent polymer film to the first polymer film so as to cover the light-modulating electrical unit. In one example, the light-modulating electrical unit is comprised of two or more sub-units and is itself formed as part of the lamination process.

### FIELD OF THE INVENTION

The present invention generally relates to multi-layer electrical devices that interact with light, and in one particular aspect to improvements in the manufacture of multi-layer electrical devices that interact with light, that is light-modulating devices, for example by their incorporation within polymer laminate films that have been suitably embossed (i.e. impressed).

### BACKGROUND OF THE INVENTION

Electrical devices that interact with light are well known. Examples include light-emitting diodes (which emit light), solar cell modules (which harvest light and turn it into electricity), and display screens (which may alter the light that they reflect). Most devices of this type use glass in one form or another as the key, transparent substrate material. This is often problematic however, since glass is typically fragile, heavy, expensive, and generally not well-suited to high-volume, low-cost mass-production. For this reason there is increasing interest in using cheaper, transparent polymeric materials in place of glass in devices of this type. Ideally, this will be combined with simple and inexpensive fabrication techniques for the devices themselves, such as the use of commercial printing processes.

A critical problem in this respect is to integrate a transparent polymer substrate into the fabrication of flexible electrical devices. Several approaches have been trialled and are being used. A common one (exemplified by the flexible touch-screen disclosed in EP 0348229) is to employ a transparent polymer sheet which has been coated on one side with a transparent electrically conducting layer. The sheet acts as a transparent electrode upon which the remainder of the device is built, usually as a multi-layer structure.

Another approach (exemplified by the photovoltaic device described in DE 19846160), is to fabricate the device on a non-transparent, flexible polymer film and then overlay a transparent polymer film upon it, to thereby exclude vapour, oxygen, or dust from the device.

While techniques such as those described above are technically successful, they are typically not amenable to high volume, low-cost mass-production manufacturing, especially in respect of devices which interact with light. The cost of manufacturing such devices may, however, be a critical factor in their physical uptake by society. Indeed, in many cases it is purely the cost and complexity of manufacturing such devices that has halted their general use and application. New inventions and improvements in respect of high-volume, low-cost mass-production manufacturing techniques are needed in order to develop practically useful, inexpensive, glass-free electrical devices that interact with light.

A range of electrical devices are currently manufactured in flexible, low-profile formats. This includes batteries, capacitors, and super-capacitors which employ flexible polymeric bases or packaging elements. For example, JP7037559, JP11086807, EP0499005, KR20010029825, JP3034519, and U.S. Pat. No. 5,650,243 describe batteries, capacitors, or super-capacitors which are manufactured by laminating such devices between two or more polymer films. Batteries, capacitors, and super-capacitors are generally far less demanding to manufacture than light-modulating devices since they do not require optical transparency in the flexible polymeric components and their layered arrangement is typically much more forgiving of minor variations in the layer thicknesses. Light-modulating devices are notoriously sensitive such variations, which often destroy their utility completely. The laminating polymers in the abovementioned batteries, capacitors, and super-capacitors are therefore primarily incorporated for the purposes of excluding vapour, oxygen, or dust, or for making such devices more rugged.

There is a need for improved multi-layer, light-modulating devices and/or methods for the improved manufacture thereof which address or at least ameliorate one or more problems inherent in the prior art.

The reference in this specification to any prior publication (or information derived from the prior publication), or to any matter which is known, is not, and should not be taken as an acknowledgment or admission or any form of suggestion that the prior publication (or information derived from the prior publication) or known matter forms part of the common general knowledge in the field of endeavour to which this specification relates.

### SUMMARY OF THE INVENTION

According to one aspect of the present invention there is provided a method for manufacturing (i.e. fabricating) light-modulating electrical devices. In a particular form, the method provides a relatively high-volume, low-cost mass-production method.

In one example embodiment, the method facilitates simultaneous co-assembly of one or more sub-units and two or more polymer films or sheets to form a light modulating electrical device.

According to another aspect, there is provided an improved light-modulating electrical device.

According to yet another aspect, the current invention seeks to address the problem of high-volume, low-cost mass production of light-modulating devices by preparing the devices as a set of readily assembled, robust sub-units which are then combined in a layered arrangement during the course of a polymer lamination process. Preferably, at least one recess is provided within one or more of the laminating polymers that is specifically designed to accommodate the assembled sub-units. In a particular form, the laminating polymers serve not only as a robust packaging device, but are integral to the assembly process itself. In another particular form, at least one of the laminating polymers is involved in or otherwise facilitates operation of the device.

In one example form, there is provided a method for manufacturing a light-modulating electrical device, the method comprising, as a single lamination process: positioning a light-modulating electrical unit at least partially within a recess, the recess provided in a first polymer film or an optically transparent polymer film; and, fixing the optically transparent polymer film to the first polymer film so as to cover the light-modulating electrical unit.

In another example form, there is provided a light-modulating electrical device, comprising: a light-modulating electrical unit positioned at least partially within a recess, the recess provided in a first polymer film or an optically transparent polymer film; and, the optically transparent polymer film fixed to the first polymer film so as to cover the light-modulating electrical unit; wherein, the device is formed during a single lamination process.

In another example embodiment there is provided a method for manufacturing (i.e. fabricating) a light-modulating electrical device, the method including the step of simultaneously assembling, or at least partly forming, a light-modulating electrical unit (which may be comprised of a plurality of sub-units) with a first polymer film at a first side, for example a top, of the unit and a second polymer film at second side, for example a bottom, of the unit.

In another example embodiment there is provided a high-volume, low-cost mass-production method for manufacturing (i.e. fabricating) light-modulating electrical devices, the method comprising a simultaneous co-assembly of:
(1) one or more distinct sub-units which, when assembled in a layered arrangement, cumulatively comprise a light-modulating electrical unit; and
(2) two or more polymer films or sheets, wherein:
   (i) at least one of the polymer films or sheets is optically transparent, and
   (ii) at least one of the polymer films or sheets is embossed (i.e. impressed) with at least one recess into which the one or more sub-units fit;
      wherein, one of the polymer films or sheets is laminated or positioned at the top of the unit and another of the polymer films or sheets is laminated or positioned at the bottom of the unit.

In another example embodiment there is provided a light-modulating electrical device, including:
(1) one or more distinct sub-units assembled in a layered arrangement to form a light-modulating electrical unit; and
(2) two or more polymer films or sheets, wherein:
   (i) at least one of the polymer films or sheets is optically transparent, and
   (ii) at least one of the polymer films or sheets is embossed (i.e. impressed) with at least one recess into which the one or more sub-units fit;
      wherein, one of the polymer films or sheets is laminated or positioned at the top of the unit and another of the polymer films or sheets is laminated or positioned at the bottom of the unit.

It should be noted that reference to embossing (i.e. impressing) to provide at least one recess should also be taken as a reference to providing at least one indentation, depression, cavity or the like.

In a particular example, one or more of the sub-units may be electrodes which drive the operation of the light-modulating electrical device.

Preferably but not exclusively, the polymer films are flexible or semi-rigid.

Preferably but not exclusively, the sub-units to be co-assembled, may be separately optimized, prepared, and fabricated so as to be suitable to their respective task of emitting, modulating, or harvesting light in an electrical device. Preferably but not exclusively, the co-assembled sub-units can be custom-designed to be readily accommodated within the housing that is provided by the recess(es) within the polymer laminate.

Preferably but not exclusively, the co-assembled sub-units may include one or more “spacers” (i.e. spacer elements or a “spacer layer”) that maintain a suitable separation between other sub-units or components which have been or are to be layered. Examples of such spacers, e.g. forming a spacer layer, include, but are not limited to, ribs, embossed structures, beads, balls, etc. In still more specific, but non-limiting examples, the spacers may be Cellgard PP or PE separator membranes (Celgard LLC) or glass bubbles of the type produced by 3M (3M™ Glass Bubbles iM30K).

Preferably but not exclusively, the sub-units and polymer films or sheets can be assembled in a high-speed, continuous, web-fed process.

Preferably but not exclusively, the electrode layers within the co-assembled sub-units can have separate electrical connections that may involve conducting wires or tabs which pass between the polymer laminate to the outside.

According to various example aspects: the light-modulating electrical unit is comprised of two or more sub-units and is at least partially formed as part of the single lamination process; the sub-units are layered films; at least one of the sub-units is an electrode; and/or at least one of the sub-units is a spacer layer or spacers.

According to various example applications there can be provided:
(i) an electrochromic device which visibly changes colour upon application of a suitable voltage,
(ii) a back-contact dye-sensitized solar cell which generates electrical current when illuminated with sunlight, and
(iii) a solid-state dye-sensitized solar cell.

In an example form, the electrochromic device listed in (i) above preferably but not exclusively comprises of a co-laminate of two transparent polymer films sandwiching a PVDF or similar membrane that has been coated on both sides with a conducting layer, (such as but not limited to silver (Ag), platinum (Pt), or indium tin oxide (ITO)) and then coated again on each side with a layer of a suitable conducting polymer such as, but not limited to Polypyrrole (PPy), PEDOT, or PANI. By way of example, upon application of a suitable voltage across the two conducting surfaces, the electrodes change colour as follows:
PPy: yellow to blue or vice versa
PEDOT: blue to sky blue, or vice versa
PANI: blue to green, or vice versa.

The sub-units described above for the electrochromic device can include, amongst others, those described in International Publication No. WO2007002989 entitled “Charge Conducting Medium” which is incorporated herein by cross-reference.

In an example form, the back-contact dye-sensitized solar cell listed in (ii) above preferably but not exclusively comprises of a co-laminate of two transparent polymer films sandwiching a multi-layer co-assembly. The latter preferably comprises of, but is not limited to, a co-assembly of the following items into a multi-layer structure in which the electrodes do not touch each other:
(I) a porous, thin titanium foil electrode upon which a layer of TiO₂ has been deposited and sintered, whereafter a suitable light-harvesting dye
(such as, but not limited to tris(2,2′-bipyridyl)ruthenium(II) perchlorate) has been adsorbed to the TiO₂ layer,
(II) a spacer which may comprise of a Celigard PP or PE separator membrane (Celgard LLC) or glass bubbles of the type produced by 3M (3M™ Glass Bubbles iM30K), and
(III) a thin titanium foil counter electrode.

The above co-assembly is included within, or at least partially within, a recess that has been embossed or impressed into at least one of the laminating polymer sheets.

The entire assembly is preferably, but not exclusively laminated on three sides and then back-filled with a suitable solvent containing the I⁻/I₃⁻ couple that is needed in dye-sensitized solar cells. The solvent may be, but is not limited to acetonitrile, glutaronitrile, methoxypropionitrile, or valeronitrile. The polymer sheets employed in the lamination may be, but are not limited to Du Pont Sirlyn, polycarbonate, and/or polyester.

In an example form, the solid state dye-sensitized solar cell listed in (iii) above preferably but not exclusively, comprises of a co-laminate of two transparent polymer films sandwiching the following sub-units (listed in sequence from bottom-to-top):
(IV) a conductive, transparent, thin, polymer electrode upon which a layer of, first, compact TiO₂ (ca. 100 nm) and, second, mesoporous TiO₂ has been deposited and sintered, whereupon a suitable light-harvesting dye (such as, but not limited to tris(2,2′-bipyridyl)ruthenium(II) perchlorate) has, thirdly, been adsorbed upon the mesoporous TiO₂ layer which has then further been photoelectrocoated with PEDOT;
(V) a highly compressible plasma-treated Gortex (PTFE-teflon) layer, coated with a gold metallic current collector electrode and an electrocoated layer of PEDOT.

The conducting layer on the transparent electrode in (IV) preferably, but not exclusively comprises of a thin layer of indium tin oxide (ITO), or a transparent conducting ink of the ELG series manufactured by NorCote Ltd (USA). The co-assembled sub-units (IV)-(V) above preferably, but not exclusively can include, amongst others, those described in the journal paper entitled “Flexible and Compressible Gortex-PEDOT Membrane Electrodes for Solid-State Dye-Sensitized Solar Cells” published in Langmuir (2010), volume 26(3), page 1452-1455, which is incorporated herein by cross-reference.

### BRIEF DESCRIPTION OF THE DRAWINGS

Embodiments of the present invention will now be described solely by way of non-limiting examples and with reference to the accompanying drawings in which:

FIG. 1 is a schematic diagram illustrating how a recessed element may be embossed or impressed into polymer sheets or films;

FIG. 2 is a schematic diagram displaying the common elements and general methodology of an example embodiment;

FIG. 3 is a schematic diagram of an electrochromic device manufactured according to an example embodiment;

FIG. 4 is a schematic diagram of a back-contact dye-sensitized solar cell manufactured according to an example embodiment;

FIG. 5 comprises three schematic diagrams (a)-(c) which illustrate a method for assembling a solid state dye-sensitized solar cell according to an example embodiment. FIG. 5(a) shows the preparation of the working electrode prior to the cell assembly. FIG. 5(b) shows the preparation of the counter electrode prior to the assembly. FIG. 5(c) shows how the various sub-units are assembled to create the final solid state dye-sensitized solar cell during the lamination process; and

FIG. 6 is a schematic illustration of several examples of electrical contacts that may be used in example embodiments.

### DETAILED DESCRIPTION OF EXAMPLE EMBODIMENTS

The following modes, given by way of example only, are described in order to provide a more precise understanding of the subject matter of a preferred embodiment or embodiments. In the figures, incorporated to illustrate features of example embodiments, like reference numerals are used to identify like parts throughout the figures.

### Example 1

### General Method for Implementation

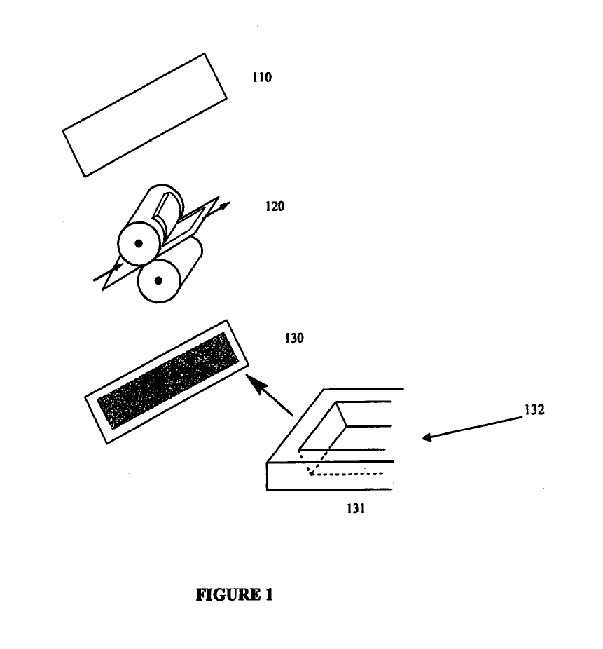

FIG. 1 illustrates a general method by which suitable recesses may be embossed or impressed into polymer films. As shown in 120, a polymer film 110 is passed between embossing rollers which contain suitable surface relief structures or protrusions, to thereby impart, under high pressure and possibly, heat, at least one recess 132, indentation, depression, cavity or the like, on the embossed or impressed polymer film 130. If desired for particular applications, a plurality of recesses can be provided in polymer film 130. It should be noted that the particular geometric shape or profile of the recess can be varied, the particular profile of recess 132 as illustrated is by way of example only.

Features can be provided within or integrated as part of the recess, for example being formed during the embossing or impressing process. Such features might include pillars, wells, further recesses, walls, protrusions and/or projections, etc. The features could be used to assist in holding, retaining or positioning a unit or sub-unit in the recess.

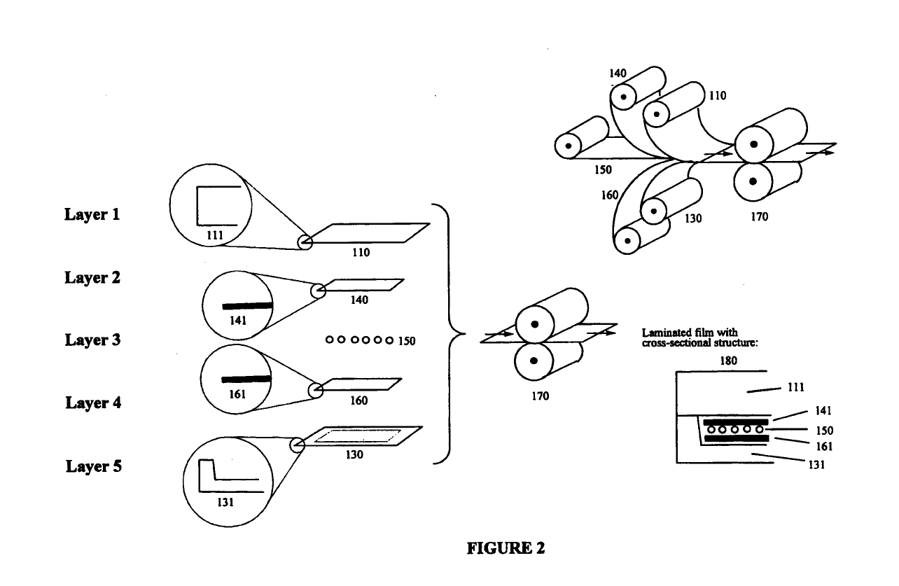

FIG. 2 schematically illustrates a general method of an example embodiment. The following items and sub-units are co-laminated by simultaneously passing between laminating rollers to form lamination 170:
(1) (Layer 1): a transparent polymer film 110 which (optionally) contains no recesses and therefore has the cross-sectional profile 111;
(2) (Layer 2): a thin electrode 140, having the cross-sectional profile 141, which may comprise of, but is not limited to:
   a. a metallic foil, such as a Ti, Pt, Al, or Au foil; or
   b. a printed conducting layer, such as a conductive, transparent or non-transparent ELG-class ink manufactured by NorCote Ltd (USA); or
   c. a deposited metallic conducting layer, such as a Al, Pt, or Au layer; or
   d. a deposited, transparent conducting layer such as an indium tin oxide (ITO) layer; or
   e. a printed or deposited conducting layer, such as a conducting polymer layer;
(3) (Layer 3): A spacer layer or spacers 150, which is used to separate the electrodes 140 and 160 and thereby prevent short-circuits. Examples of such spacers include, but are not limited to, ribs, embossed structures, beads, balls, etc. In still more specific, but non-limiting examples, the spacer layer may be a Cellgard PP or PE separator membrane (Celgard LLC) or glass bubbles of the type produced by 3M (3M™ Glass Bubbles iM30K);
(4) (Layer 4): A thin counter-electrode 160, having the cross-sectional profile 161, which may be comprised of, but is not limited to, any of the same materials described in (2)a-e above;
(5) (Layer 5): A polymer film 130, which has been embossed or impressed to have at least one recess, the polymer film 130 has the exemplary cross-sectional profile 131, in which the electrodes and spacers of (2)-(4) above can be accommodated.

Hence, there is provided a method for manufacturing a light-modulating electrical device. The method includes, as a single lamination process, positioning the light-modulating electrical unit (e.g. formed of sub-units being thin electrode 140, spacer layer 150, thin counter-electrode 160) at least partially within a recess provided in the polymer film 130 (i.e. a first polymer film). As part of the single lamination process, the transparent polymer film 110 (i.e. an optically transparent polymer film) is fixed to the polymer film 130 so as to cover the light-modulating electrical unit.

The upper right-hand detail of FIG. 2 shows a physical method of combining each of these layers into a single laminated device or product. Each layer would typically be continuously drawn off its own roll and combined, i.e. laminated, into a single laminate 170. The method of lamination or fixing layers may involve any known method, including: (i) effectively, melting the upper and lower polymer sheets into each other (that is, by application of a hot-rolled lamination technique), or (ii) effectively gluing the upper and lower polymer sheets to each other (that is, by the application of, and intermediacy of a suitable adhesive; the adhesive may be activated by pressure, heat, light, or any other suitable method). In the case where an adhesive is used to effect lamination, it is to be understood that all of the techniques described in this and the other examples provided herein would typically be adapted to include the incorporation of an adhesive coating between relevant polymer films and sub-units involved in the lamination.

Following the lamination process, the final film has the exemplary cross-sectional profile 180. By way of illustration, the cross-sectional profile 180 of the final film includes the cross-sectional profiles of an upper transparent layer 111 below which lies, in the recessed cross-sectional profile 131, an upper electrode 141 separated by spacer layer 150 from a lower electrode 161. One of the electrodes would be the working electrode of the light modulating device and the other would be the counter electrode of the light modulating device.

Optionally, the recessed chamber containing electrode 140, spacer layer 150, and counter-electrode 160 may contain a liquid electrolyte that is introduced into a chamber formed by, or at least partially by, the recess, or is introduced into the recess itself, before, during, or in the process of lamination.

In various examples, the ordering of the transparent film and the embossed (i.e. impressed) film could be changed, for example the embossed film could be positioned as an upper layer and the transparent film could be positioned as a lower layer. Furthermore, either or both films could be embossed to each provide at least one recess. Thus, the light-modulating electrical unit could also at least partially fit into a further recess provided in the first polymer film or the optically transparent polymer film, so that both layers have recesses to accommodate the electrical unit. Still furthermore, both films could be transparent.

While sealed within the polymer laminate, the upper and lower electrodes 140 and 160 are generally arranged so as to be connected electrically to an external electrical circuit by the presence of electrical connections within the laminate that extend to the outside.

Optionally, the recessed chamber may have a tailored profile to incorporate in-built spacer elements to prevent one or more of the upper or lower electrodes from sticking to the laminating polymer films and thereby allowing the movement of liquid electrolyte to that electrode.

### Example 2

### Fabrication of an Electrochromic Device

This example describes an improved method of fabrication of an electrochromic device, for example of the type described in International Publication No. WO2007002989 entitled “Charge Conducting Medium” which is incorporated herein by cross-reference.

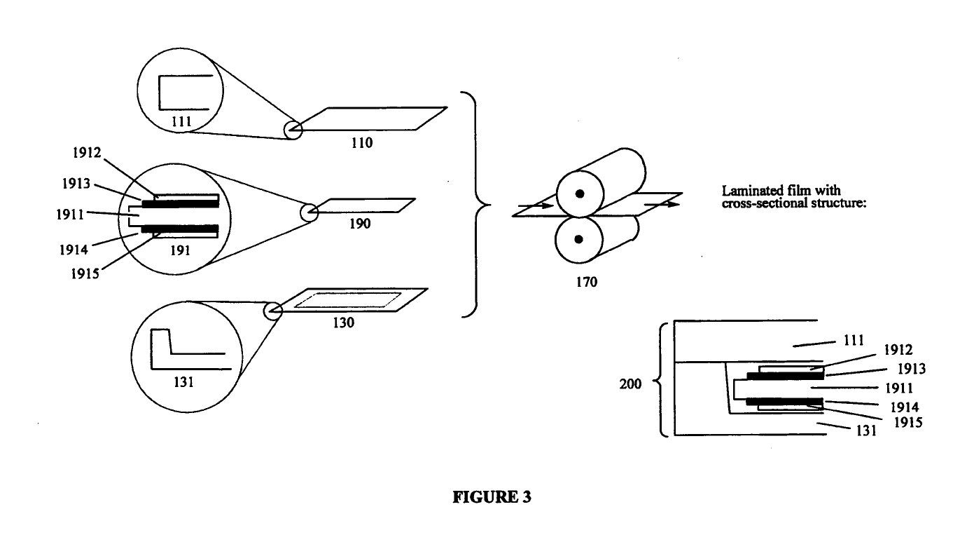

FIG. 3 describes a method for manufacturing an electrochromic device. A PVDF membrane 1911 is coated on either side with a conducting layer, such as Ag, Pt, or ITO. The upper conducting layer 1913 is the working electrode and the lower conducting layer 1914 is the counter electrode. The upper conducting layer 1913 (working electrode) is then over-printed on the top side with a conducting polymer layer 1912, which may be PPy, PEDOT, or PANI. The lower conducting layer 1914 (counter-electrode) is overprinted with a different conducting polymer 1915, such as for example, PEDOT. The resulting sub-assembly is designated 190 in FIG. 3. Sub-assembly 190 is co-assembled with a transparent polymer film 110, of cross-sectional profile 111, and an embossed polymer film 130, having a cross-sectional profile 131, and subjected to lamination to produce laminate 170. The resulting film 200 has the exemplary cross-sectional structure shown. Film 200 includes a transparent upper polymer film 111 sandwiching with a lower, recessed polymer film of cross-sectional profile 131, where the recess contains the PVDF membrane 1911 which is sandwiched with an upper working electrode 1913 upon which is deposited a conducting polymer layer 1912, and a lower counter-electrode 1914 upon which is deposited a second conducting polymer 1915. The upper and lower electrodes are capable of being connected to an external circuit by the use and presence of a variety of types of connectors.

When a moderate voltage (for example 1-2 V) is applied across the electrodes, the conducting polymers change colour according to:
PPy: yellow to blue or vice versa
PEDOT: blue to sky blue, or vice versa
PANI: blue to green, or vice versa.

### Example 3

### Fabrication of a Back-Contact Dye-Sensitized Solar Cell

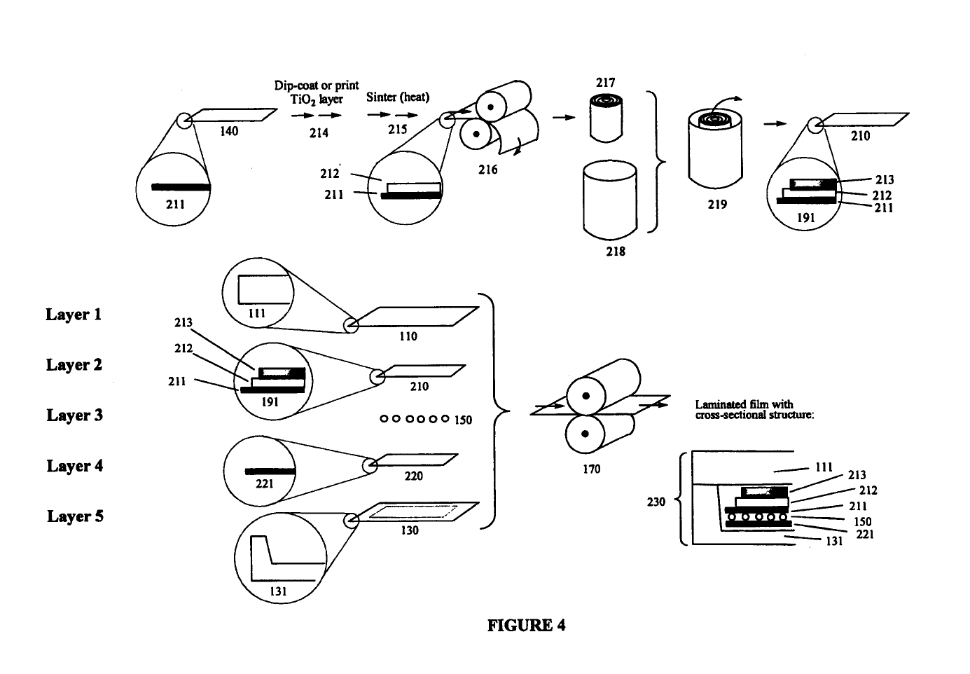

The top sequence in FIG. 4 depicts a method of pre-treating the working electrode in a back-contact dye-sensitized solar cell. The lower schematic in FIG. 4 depicts a process of assembling a back-contact dye-sensitized solar cell.

Referring to the top sequence in FIG. 4:

A thin, porous titanium foil 140, having cross-section 211 is dip-coated or printed with a TiO₂ layer as shown in step 214. The TiO₂ on the coated foil is then sintered by heating at step 215. After sintering, the foil has the cross sectional profile 211, coated with a TiO₂ layer 212. The foil is then rolled up at step 216, with spacers placed between the successive layers, to thereby yield the rolled up but separated foil 217. This separated foil 217 is placed in a bath 218 containing a solution of a suitable dye such as ruthenium(II) tris(2,2′-bipyridyl) perchlorate and allowed to soak at step 219. After soaking for a period of time, for example 24 hours, the TiO₂ layer has adsorbed significant quantities of the dye. The foil 217 is then removed from the bath 218, washed, dried, and unrolled to give the working electrode 210, which has the cross-sectional structure 191, involving the titanium foil 211 coated with the TiO₂ layer 212, upon which a layer of the dye 213 is adsorbed.

Referring to the lower schematic in FIG. 4:

A 5-layer co-assembly of the following is then formed in the sequence (top-to-bottom) given below and laminated as shown in FIG. 4:
(layer 1): An upper transparent polymer sheet 110 having the cross-sectional structure 111,
(layer 2): An upper working electrode 210, which has the cross-sectional profile 191 (containing the titanium foil 211, coated with sintered TiO₂ 212, upon which a layer of dye 213 has been adsorbed),
(layer 3): A spacer layer 150,
(layer 4): A lower counter-electrode 220, which comprises of a virgin titanium foil having cross-section 221,
(layer 5): A lower embossed polymer film containing a recess and of cross-sectional profile 131.

The above co-assembly is laminated to form laminate 170, whilst including a liquid electrolyte containing the needed I⁻/I₃⁻ couple, thereby yielding a polymer film that has the cross-sectional arrangement 230; namely.
an upper transparent polymer film 111 sandwiching a lower polymer film 131 which contains an embossed recess into which the back-contact solar cell fits. The assembled back-contact solar cell has the structure:
   an upper electrode 211 upon which has been coated a TiO2 layer 212, which has itself been coated with a suitable dye 213;
      a spacer 150 to separate the electrodes and prevent short circuits;
      a lower electrode 221, which acts as the counter electrode;
      a liquid electrolyte inside the embossed recess and about the spacer elements and electrodes.

Upon illumination with sunlight, the laminated back-contact solar cell yields a voltage between the two electrodes. An external circuit connected to the two electrodes by connecting elements yields a current as a result of the influence of sunlight on the back-contact solar cell.

The laminated polymer structure of the solar cell is amenable to high-volume, low-cost mass production. The laminated polymer layers protect the solar cell and lengthen its lifetime.

The laminating polymer films may be, for example, Du Pont Sirlyn, polycarbonate, or a polyester. The liquid in the electrolyte may be, for example, acetonitrile, glutaronitrile, methoxypropionitrile, or valeronitrile.

The lamination process may involve three sides of the device being laminated first, after which the liquid electrolyte is introduced, with the fourth side being laminated thereafter. Alternatively, the liquid electrolyte may be introduced into the recessed cavity immediately prior to lamination, which is so constructed as to trap the liquid electrolyte within the laminated polymer film.

### Example 4

### Fabrication of a Solid-State Dye-Sensitized Solar Cell

This example describes an improvement of the method of fabrication of a solid-state dye-sensitized solar cell, for example of the type described in the journal paper entitled “Flexible and Compressible Gortex-PEDOT Membrane Electrodes for Solid-State Dye-Sensitized Solar Cells” published in Langmuir (2010), volume 26(3), page 1452, which is incorporated herein by cross-reference.

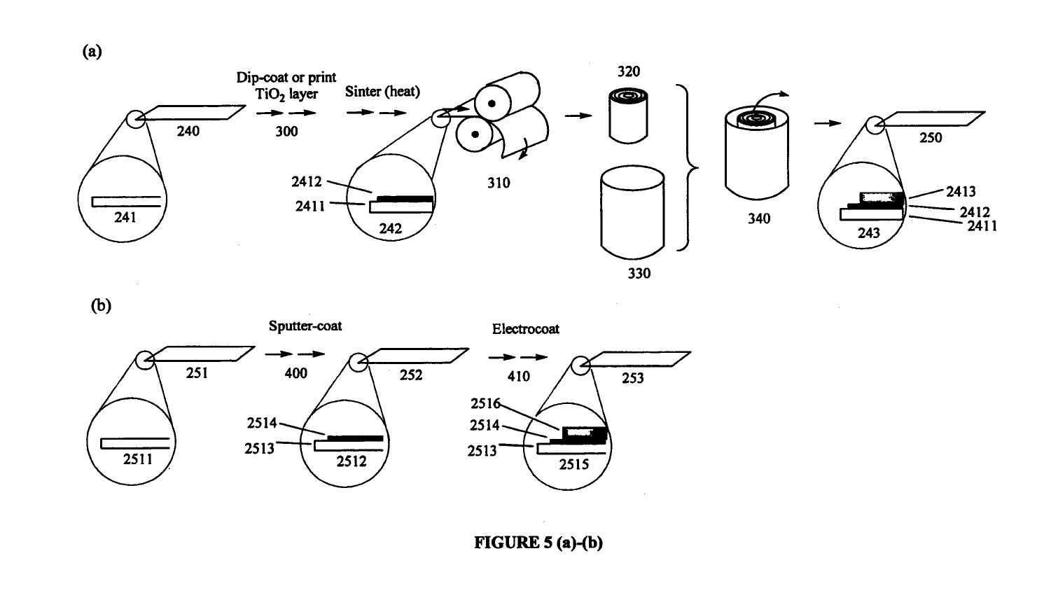

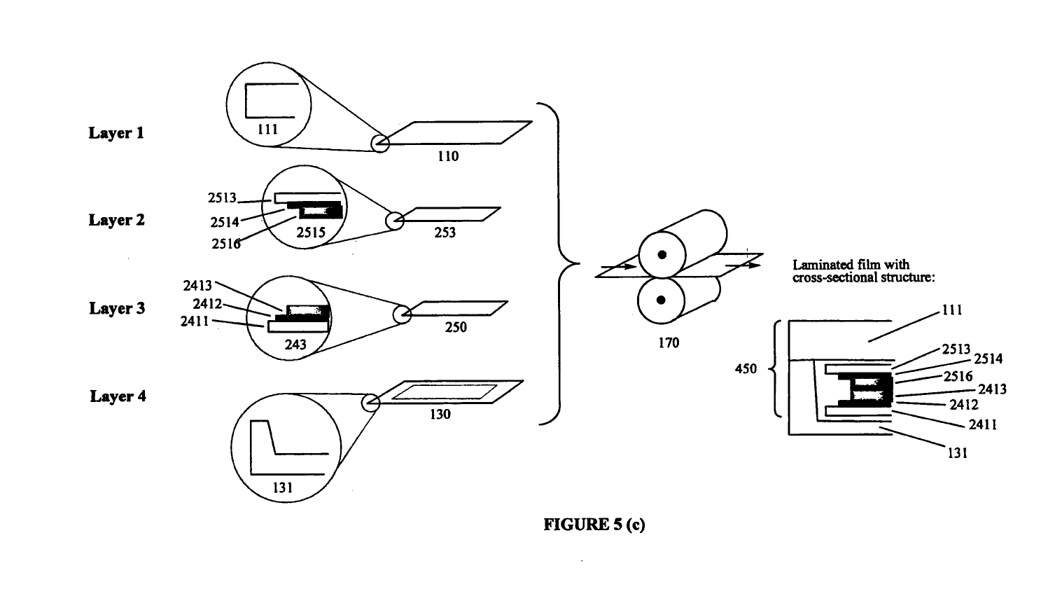

FIG. 5(a) depicts the preparation of the working electrode sub-unit of a solid-state dye-sensitized solar cell prior to its final assembly. A polymer sheet 240 coated with a transparent conductive layer, such as indium tin oxide (ITO) or a transparent conductive ink of the ELK-series produced by NorCote, has the cross-sectional profile 241. The sheet is dip-coated or printed with a specially-formulated TiO₂ paste in step 300. The paste is then sintered using heat or pressure to yield a nanoparticulate TiO₂ coating 2412. The resulting sheet of cross-sectional profile 242 is then rolled up (at step 310), whilst ensuring that a small gap exists between each successive sheet in the roll. The resulting rolled up sheet 320 is then placed into a drum-like container 330 containing a coating solution, where it is, first, coated by adsorption of a suitable light-harvesting dye, followed by electrocoating of a PEDOT layer. Step 340 shows the rolled up sheet 320 in the drum 330 during this treatment. After completion of step 340, the sheet is removed from the drum, dried, and unrolled. The resulting sheet 250, now has the cross-sectional profile 243, which comprises of a transparent polymer sheet with transparent conducting layer 2411, which is overcoated with, first, a sintered TiO₂ layer 2412, and then, second, with a TiO₂-dye-PEDOT layer 2413.

FIG. 5(b) depicts the preparation of the counter electrode sub-unit of a solid-state dye-sensitized solar cell prior to its final assembly. The base substrate 251 is, for example, a Gortex membrane which has been coated with ca. 10 nm poly(maleic anhydride) using low-power plasma polymerization. The resulting plasma-treated Gortex membrane has the cross-sectional profile 2511. The membrane is then sputter-coated at step 400 with a layer (ca. 40 nm thick) of gold, titanium, or nickel to reduce the sheet resistance. The Gortex electrode is now designated 252 and has the cross-sectional profile 2512. It comprises the original plasma-treated membrane 2513 overcoated with a layer of gold, titanium, or nickel 2514. In the following step 410, one side of the membrane 252 is subjected to a vapour-phase polymerisation of PEDOT. The final form of the Gortex membrane 253 has a cross-sectional profile 2515 involving a plasma-treated Gortex base 2513, overcoated with a layer 2514 of gold, titanium, or nickel, overcoated by a layer 2516 of PEDOT.

FIG. 5(c) illustrates the assembly of the final solid-state dye-sensitized solar cell. A 4-layer co-assembly is made and laminated as follows (in the order top-to-bottom, as shown in FIG. 5(c)):
(layer 1): An upper transparent polymer sheet 110 having the cross-sectional structure 111,
(layer 2): An upper counter electrode 253, which has the cross-sectional profile 2515 (containing the original plasma-treated Gortex base 2513, overcoated with a layer 2514 of gold, titanium, or nickel, which has been further overcoated with a layer 2516 of PEDOT),
(layer 3): A lower working electrode 250, which has the cross-sectional profile 243, comprising of a transparent polymer base coated with a transparent conducting layer 2411, which has been overcoated with sintered TiO₂ 2412, upon which a layer of dye and PEDOT 2413 has been deposited.
(layer 4): A lower embossed polymer film containing a recess of cross-sectional profile 131.

Note that there is no spacer between layers 2 and 3 of the assembly. Instead, these layers are compressed together by the lamination process. A key advantage of the process is that the Gortex is highly compressible, thereby ensuring good electrical contact between layer 2 and 3. Preferably, there is no liquid electrolyte present in the assembly, which is fully solid-state.

The final assembly has the cross-sectional profile 450. The assembly comprises the upper polymer sheet 111 laminated to the lower polymer sheet 131. Within the recess in the lower polymer sheet is the solid-state dye-sensitized solar cell, which comprises of the counter electrode (plasma-treated Gortex 2513, overcoated with a conducting metallic layer 2514 and a layer of PEDOT 2516, compressed against the working electrode, which comprises the transparent conductive sheet 2411, overcoated with sintered TiO₂ 2412 and a layer of dye and PEDOT 2413).

Upon illumination with sunlight, the laminated solid-state solar cell yields a voltage between the two electrodes.

The laminated polymer structure of the solar cell is amenable to high-volume, low-cost mass production. The laminated polymer layers provide the required compression of the two electrodes. The laminated polymer layers also protect the solar cell and lengthen its lifetime.

### Example 5

### Types of Electrical Contacts

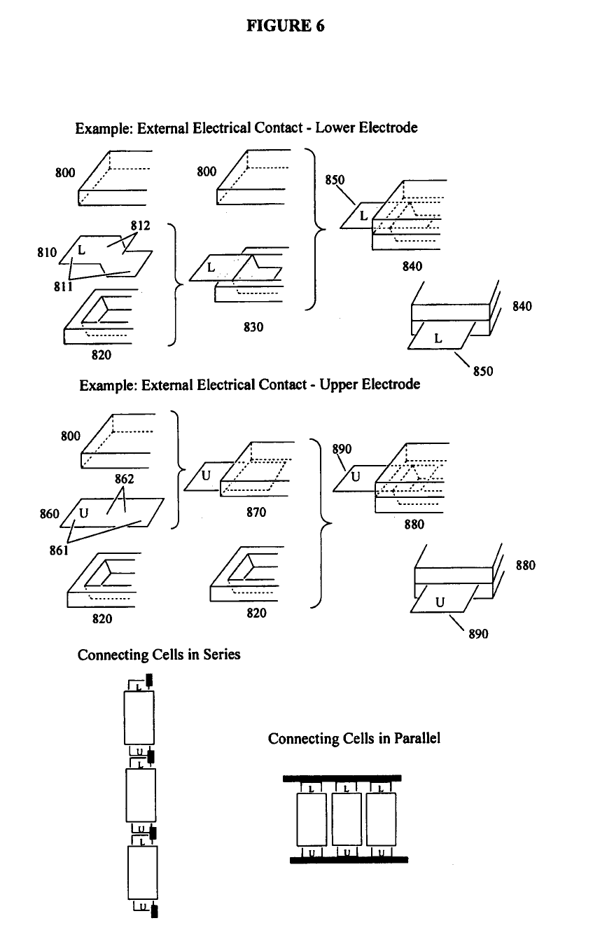

There is a need for external electrical connections that connect to the electrodes inside the laminate. FIG. 6 depicts examples of suitable external electrical contacts. The upper schematic in FIG. 6 depicts an insert that may be employed to provide an external electrical contact with the lower electrode in various example devices. The middle schematic of FIG. 6 depicts an insert that may be employed to provide an external electrical contact with the upper electrode in various example devices. These electrodes, that can be provided as inserts, can have a partial surface area that is conducting and a partial surface area that is insulating.

Referring to the upper schematic in FIG. 6:

In cases where the lower electrode in the device to be incorporated in the laminate is an exposed metal or conducting material (such as is described in Example 1), an insert 810 can be included in the assembly and lamination process as shown in 830 and 840 (where 800 is the upper polymer film of the laminate and 820 is the lower polymer film). The insert 810 may comprise of a thin metal or conductive material, where the conducting surface is exposed 811 on each end, with other areas 812 made insulating by coating with an insulator. When included in an assembly of the type described in Example 1 as shown in the upper schematic in FIG. 6, the lower exposed, conducting area 811 will necessarily be pressed into close contact with the lower, exposed, conducting electrode of the device incorporated within the recess 820 of the lower plastic sheet. The upper exposed area 811 (marked “L”) of insert 810 would however lie outside of the laminate. Thus, an external electrical contact would be established between the upper exposed, conducting area 850 (marked “L”) and the lower electrode of the device incorporated in the recess 830 of the lower polymer sheet. The insulating areas 812 will ensure that this electrical connection will not short-circuit with the upper electrode of the device incorporated in the recess 830.

Referring to the middle schematic in FIG. 6:

In cases where the upper electrode in the device to be incorporated in the laminate is an exposed metal or conducting material (such as is described in Example 1), an insert 860 can be included in the assembly and lamination process as shown in 870 and 880 (where 800 is the upper polymer film of the laminate and 820 is the lower polymer film). The insert 860 may comprise of a thin metal or conductive material, where the conducting surface is exposed 861 on each end, with other areas 862 made insulating by coating with an insulator. When included in an assembly of the type described in Example 1 as shown in the middle schematic in FIG. 6, the right-hand exposed, conducting area 861 will necessarily be pressed into close contact with the upper, exposed, conducting electrode of the device incorporated within the recess 820 of the lower plastic sheet. The left-hand exposed area 861 (marked “U”) of insert 860 would however lie outside of the laminate. Thus, an external electrical contact would be established between the outer exposed, conducting area 890 (marked “U”) and the upper electrode of the device incorporated in the recess 830 of the lower polymer sheet. The insulating areas 862 will ensure that this electrical connection will not short-circuit with the lower electrode of the device incorporated in the recess 830.

Referring to both the upper and middle schematics of FIG. 6:

In cases where one or more electrodes of the device to be incorporated in recess 820 do not have conductive surfaces directly exposed during lamination, the inserts 810 or 860 may be physically attached to the electrodes prior to the assembly being laminated. This attachment would involve a method that creates direct electrical connectivity between the conduction layer of the electrode and the inner exposed conduction surface 811 or 861 of the insert 810 or 860, respectively. For example, the insert may be glued to the electrically conductive surface of the electrode using a conducting glue. Alternatively, the insert may be soldered to the electrically conductive surface of the electrode. After connecting the insert, the assembly may proceed as normal. The resulting device will have an exposed electrical contact 850 or 890 at one side of the laminate.

For convenience and to avoid electrical short circuits, the upper electrode contact would typically be inserted at the opposite end of the device to that of the lower electrode contact. The two inserts may, for example, be included at the top and bottom of the device, or on the left and right of the device.

The lower schematic in FIG. 6 illustrates methods of connecting the external electrical contacts of cells constructed in this way. Cells may be arranged and connected in a “head-to-toe” arrangement (series connection) as shown in the left-hand schematic at the bottom of FIG. 6. Alternatively, cells may be arranged in a “side-by-side” arrangement (parallel connection).

Optional embodiments of the present invention may also be said to broadly consist in the parts, elements and features referred to or indicated herein, individually or collectively, in any or all combinations of two or more of the parts, elements or features, and wherein specific integers are mentioned herein which have known equivalents in the art to which the invention relates, such known equivalents are deemed to be incorporated herein as if individually set forth.

It will be appreciated that the embodiments described above are intended only to serve as examples, and that many other embodiments are possible with the spirit and the scope of the present invention.

1. A method for manufacturing a light-modulating electrical device, the method comprising, as a single lamination process:
positioning a light-modulating electrical unit at least partially within a recess, the recess provided in a first polymer film or an optically transparent polymer film; and,
fixing the optically transparent polymer film to the first polymer film so as to cover the light-modulating electrical unit.

2. The method of claim 1, wherein the light-modulating electrical unit is comprised of two or more sub-units and is at least partially formed as part of the single lamination process.

3. The method of claim 2, wherein the sub-units are layered films.

4. The method of claim 2, wherein at least one of the sub-units is an electrode.

5. The method of claim 2, wherein at least one of the sub-units is a spacer or spacer layer.

6. The method of claim 1, wherein at least one electrical connection is provided to connect the electrode to outside the device.

7. The method of claim 1, wherein the light-modulating electrical device is an electrochromic device which visibly changes colour upon application of a suitable voltage.

8. The method of claim 1, wherein the light-modulating electrical device is a back-contact dye-sensitized solar cell.

9. The method of claim 1, wherein the light-modulating electrical device is a solid-state dye-sensitized solar cell.

10. The method of claim 1, wherein the light-modulating electrical unit, the first polymer film and the optically transparent polymer film are simultaneously co-assembled as part of the single lamination process.

11. The method of claim 1, wherein the light-modulating electrical unit at least partially fits into a further recess provided in the first polymer film or the optically transparent polymer film.

12. The method of claim 1, wherein the first polymer film is optically transparent.

13. The method of claim 1, wherein the first polymer film and the optically transparent polymer film are flexible.

14. The method of claim 1, wherein a liquid electrolyte is introduced into a chamber formed by the recess and the covering optically transparent polymer film during the lamination process.

15. The method of claim 1, wherein the recess is embossed in the first polymer film or the optically transparent polymer film by at least one roller as a preceding step to the lamination process.

16. A light-modulating electrical device, comprising:
a light-modulating electrical unit positioned at least partially within a recess, the recess provided in a first polymer film or an optically transparent polymer film; and,
the optically transparent polymer film fixed to the first polymer film so as to cover the light-modulating electrical unit.

17. The device of claim 16, wherein the device is formed during a single lamination process.

18. The device of claim 16, including at least one electrode provided as an insert having a partial surface area that is conducting and a partial surface area that is insulating.

19. The device of claim 16, including a spacer layer.

20. The device of claim 16, wherein the recess is provided in the first polymer layer and the recess also holds a liquid electrolyte.
